(19) United States
(12) Patent Application Publication
(10) Pub. No.: US 2002/0001978 A1
(43) Pub. Date: Jan. 3, 2002

(54) Method for manufacturing double-faced semiconductor circuits

(76) Inventor: Christian Fleitz, Tours (FR)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 09/863,833

(22) Filed: May 23, 2001

(30) Foreign Application Priority Data
May 23, 2000 (FR) 00/06572

(51) Int. Cl. H01L 21/00

(52) U.S. Cl. 438/800; 438/928

(57) ABSTRACT

A method for developing a pattern, on a photosensitive material of negative type, including the steps of depositing the photosensitive material on a surface of a semiconductor substrate; drying the material to obtain the adherence of the material while maintaining some flexibility to it; exposing, according to a desired pattern, regions of the photosensitive material; and annealing to solidify the photosensitive material.

### BACKGROUND OF THE INVENTION

1. Field of the Invention

The present invention generally relates to the manufacturing of semiconductor components. More specifically, the present invention relates to the manufacturing of semiconductor components for which patterns are formed on the two surfaces of a wafer, the pattern of one surface being aligned with respect to the pattern of the other surface.

2. Discussion of the Related Art

For many semiconductor devices, especially power devices, it is necessary to perform the “double-faced” processings implementing the etching of at least one photosensitive product layer, hereafter called resist, on the two surfaces of a semiconductor wafer according to patterns aligned with respect to one another. The pattern of each surface is then individually defined by a corresponding etch mask.

To form a pattern on a first surface, hereafter called the front surface, according to a pattern present on a second surface, hereafter called the rear surface, there exist machines, such as, for example, equipment MA150 sold by Karl Suss Company. Such equipment includes optical devices enabling localization of a pattern present on the rear surface, which enables appropriately placing a wafer to form, on the front surface, the desired pattern with respect to the rear surface pattern.

To simultaneously form, on the two surfaces of a semiconductive wafer, patterns aligned with respect to one another, there exist machines such as, for example, machine MA25 sold by Karl Suss Company. However, such a machine poses problems, especially in terms of alignment accuracy of the front and rear masks and of repeatability (drifts).

It is thus preferred, to perform double-faced processings, to use a machine of the type of machine MA150 of the above-mentioned Company according to the sequence of steps discussed hereafter in relation with FIG. 1.

FIG. 1 shows the sequence of steps conventionally implemented to perform a double-faced etching of a resist and of at least one underlying layer, the two surfaces being etched according to patterns aligned with respect to one another. According to this method, one of the two surfaces is first processed, for example the rear surface. The processing of this surface includes the following steps:

1. Deposition on the front surface of a layer of negative resist. More specifically, the resist is generally deposited in liquid form by centrifugation.

2. First anneal. The wafer is heated, or annealed, to solidify the resist. This first anneal generally consists of a relatively short stay on a plate heated to a relatively high temperature with respect to the ambient temperature. For a resist of type SC 100 of Arch Chemicals Company, the wafer is heated for substantially one minute at a temperature of approximately 85° C.

3. Turning over of the wafer and deposition of resist on the rear surface.

4. Second anneal, also intended for solidifying the resist. This step cannot be performed similarly to step 2 of the first anneal. A batch stoving at a temperature identical to that of first anneal step 2 is then performed, the solidification conditions being set by the sole photosensitive material.

5. Exposure to an ultraviolet radiation of one of the two surfaces, for example the rear surface. This exposure of the rear surface is performed by means of a mask including transparent portions and portions that are opaque to radiation. The resist regions underlying the transparent portions are then polymerized while the regions underlying the opaque portions keep their initial structure.

6. “Developing” the rear surface. This step consists of submitting the resist to a specific etching, in the considered case of a negative etching, of removing the sole non-polymerized (unexposed) regions from the rear surface. It should be noted that at this stage, the front surface resist is protected against such an etching. This protection is ensured by an exposure of the entire front surface, performed before or after step 5 of selective exposure of the front surface.

7. Third anneal, intended for removing by evaporation the traces of etch solvents used at preceding step 6 of rear surface developing and enhancing the hardening of the resist on both surfaces to guarantee its resistance during the next processing. This third anneal is thus performed in temperature conditions adapted to hardening the resist. In the considered case of a resin of type SC 100, the wafer spends some thirty minutes in an oven at approximately 130° C.

8. Rear surface processing. The sole rear surface is submitted to any processing, for example an etching of the portions of the underlying layer exposed by the opening of the resist layer during step 6 of development of the rear surface.

9. First removal, which ends the rear surface processing by a cleaning step, essentially consisting of removing the resist from both wafer surfaces.

A front surface processing method that can be deduced from that previously discussed for the rear surface is then implemented. Starting from first removal step 9, and after appropriate cleanings, the sequence of steps then is the following:

11. Deposition of a resist layer on the front surface.

12. Fourth anneal, intended for solidifying the resist deposited on the front surface, like the first anneal of step 2.

13. Deposition on the rear surface of a resist layer.

14. Fifth anneal of the wafer, identical to the second anneal of step 4.

15. Selective exposure of the front surface, by means of a mask having a position adjusted according to the rear surface pattern.

16. Development of the front surface, consisting of removing the non-polymerized regions of the resist on the sole front surface, the rear surface being protected by an exposure of its entire surface, previously performed just before or after step 15 of selective exposure of the front surface.

17. Sixth anneal, identical to the third anneal of step 7, intended for evaporating solvents and hardening the resist.

18. Front surface processing. Similarly to rear surface processing step 8, the sole front surface is submitted to any processing, for example, of etching of the front surface in the resist openings formed during step 16 of front surface development.

19. Second removal, similar to removal step 9, that is, total removal of the resist on both wafer surfaces.

Various alternatives are possible in a conventional process, especially in the operations of deposition of the photosensitive material. Thus, the different hardening and/or evaporation anneals may be performed differently. However, their respective temperature conditions are identical. Indeed, the relatively high solidification/hardening temperature, that is, a temperature greater than the ambient temperature, depends on the sole nature of the photosensitive material (resist) used. More specifically, specific first and fourth anneal steps 2 and 12 have been considered as being individually performed on a heating plate as a non-limiting example only. It is possible to implement instead of these steps a stove anneal similar to those performed at second, third, fifth, and sixth anneal steps 4, 7, 14, and 17.

However, conventional double-faced processing sequences hinge, as previously discussed, around the repeating, for each wafer surface, of the processing specific to a surface. Such a repetition is conventionally indispensable to observe the rear surface pattern upon placing, or “centering”, of the front surface exposure mask.

Such a method is particularly long and expensive.

### SUMMARY OF THE INVENTION

The present invention thus aims at providing a novel double-faced photographic etching method which is of particularly simple and inexpensive implementation.

To achieve this and other objects, the present invention provides a method for processing front and rear surfaces of a semiconductor substrate, including the steps of:

depositing on the front surface a photosensitive material of negative type;

annealing the substrate at a relatively high temperature;

turning over the substrate;

depositing the photosensitive material on the rear surface;

drying said material so that it adheres to the substrate while keeping some flexibility;

exposing, according to a desired pattern, regions of the photosensitive material on the rear surface;

annealing to solidify the photosensitive material;

turning over the substrate and realigning it using rear surface deformations defining the first pattern in the photosensitive material, obtained by the preceding steps of drying, rear surface exposing and annealing;

exposing the front surface, according to a second etch pattern;

simultaneously developing the two surfaces; and

simultaneously processing on both surfaces the substrate portions exposed by the openings in the photosensitive material performed at the preceding step of simultaneously developing the two surfaces.

According to an embodiment of the present invention, the drying step is performed at a temperature close to the ambient temperature.

According to an embodiment of the present invention, the drying step is performed at substantially 21° C. for thirty minutes.

According to an embodiment of the present invention, the drying step comprises a ten-second stay on a plate heated to approximately 65° C.

According to an embodiment of the present invention, the annealing step to solidify the photosensitive material is performed at a temperature ranging between 80° C. and 100° C.

According to an embodiment of the present invention, the step of simultaneous development of the two surfaces includes the steps of removing from the two surfaces the selectively unexposed regions of the photosensitive material; and annealing, at a relatively high temperature, to evaporate etch and hardening solvents of the regions of the photosensitive material that have been left in place.

According to an embodiment of the present invention, the step of simultaneous processing of the substrate on the two surfaces includes a double-faced doping.

According to an embodiment of the present invention, the step of simultaneous processing of the substrate on the two surfaces includes a double-faced etching of the same material.

According to an embodiment of the present invention, anneal step d) is performed at a temperature ranging between 80° C. and 100° C.

The foregoing objects, features and advantages of the present invention, will be discussed in detail in the following non-limiting description of specific embodiments in connection with the accompanying drawings.

### BRIEF DESCRIPTION OF THE DRAWINGS

FIG. 1 is a flowchart illustrating in a simplified manner the sequence of steps of a conventional double-faced etching process on a layer of a given material;

FIG. 2 is a timing diagram illustrating the sequence of steps of a method of double-faced processing of a semiconductor substrate according to the present invention; and

FIG. 3 is a partial simplified cross-section view of a semiconductor wafer at an intermediary step of its manufacturing according to the present invention.

### DETAILED DESCRIPTION

For clarity, similar or identical steps have been designated with similar or identical names in the different drawings. Further, as usual in the representation of integrated circuits, FIG. 3 is not drawn to scale.

A feature of the present invention is to use the photosensitive materials in an unusual way, indeed opposite to usual specifications.

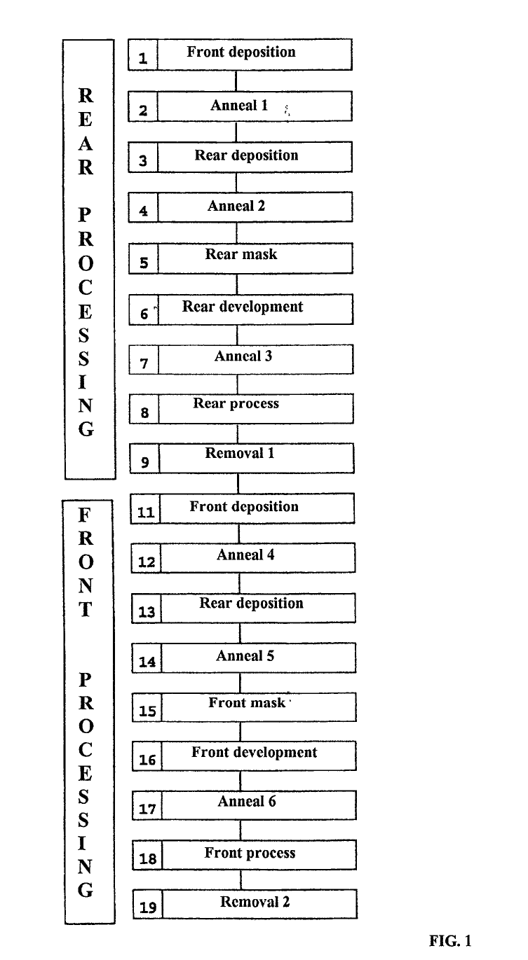

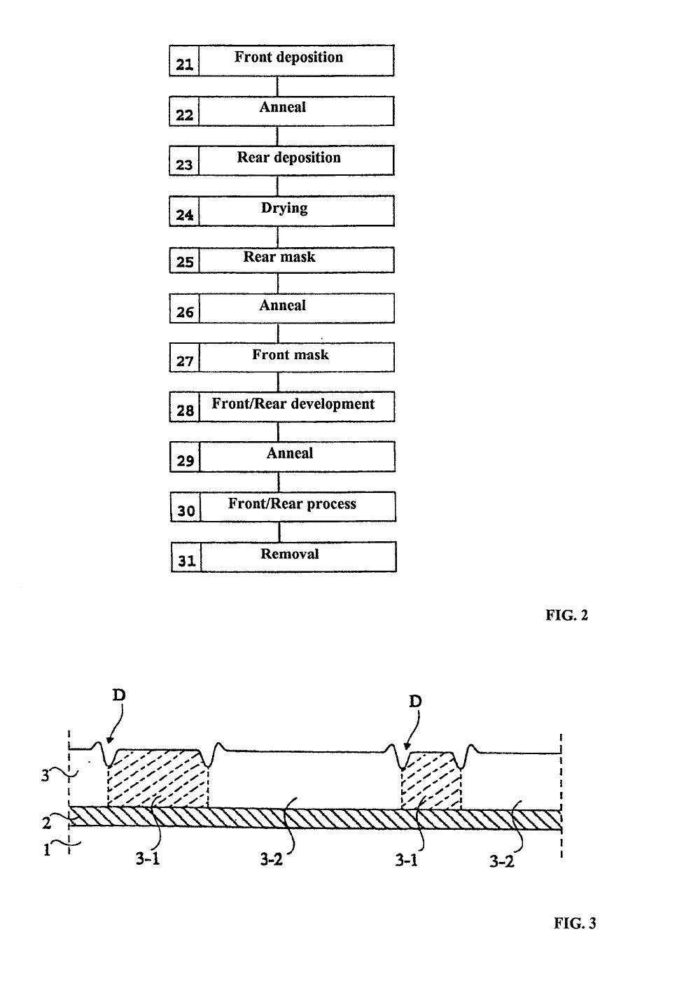

More specifically, the present invention provides replacing, in a double-faced processing, the development and processing of a first surface before processing the second one, as discussed in relation with FIG. 1, with an optical development of a desired processing pattern at the surface of a layer of a photosensitive material after exposure thereof to an ultraviolet radiation. A sequence of steps specific to the complete processing the sole first surface (rear surface) is replaced with a thermal processing which is particularly simple to implement. The characteristic sequence of a double-faced processing method implementing such a development according to the present invention is discussed hereafter in relation with the flowchart of FIG. 2.

FIG. 2 illustrates different steps of a method according to the present invention for processing a resist layer as well as the underlying substrate, on the two surfaces of a semiconductor wafer, the processing patterns of each of the surfaces being aligned with respect to one another. More specifically, it is assumed that the front and rear surfaces of the substrate are formed of a same material and must undergo a same processing. This material can be the very substrate, or a specifically deposited layer. The specific case of an etching of the substrate surfaces will be considered hereafter as a non-limiting example. “Substrate” then designates a uniformly doped silicon wafer as well as epitaxied areas and/or areas specifically doped by diffusion/implantation formed on or in a massive substrate, as well as an insulating or conductive layer, for example metallic, specifically formed on both surfaces of a substrate.

As a non-limiting example, it is assumed hereafter that the resist is of negative type. It is, for example, a resin of family Waycoat SC RESIST sold by Arch Chemicals Company, such as resins SC100, SC180, or SC450.

The processing according to the present invention includes the steps of:

21. Depositing a layer of a photosensitive material, or resist, for example by centrifugation, on a first surface or front surface of a semiconductor substrate.

22. Solidifying the resist on the front surface, which is performed in accordance with a conventional sequence by an anneal. This anneal can either be a stoving or, preferably, a stay on a heating plate. It is performed at a relatively high temperature as compared to the ambient temperature. For a resin of type SC100, the anneal temperature is included between 80 and 100° C., for example 85° C. The resist being solidified at the front surface, the semiconductor wafer is turned over and the resist is deposited on the rear wafer surface at the next step 23.

23. Depositing resist on the rear surface.

Steps 21 to 23 are identical to steps 1 to 3 or 11 to 13. The method of the present invention differs from the state of the art by the following step 24.

24. Drying. According to the present invention, the resist is dried at a relatively low temperature, that is, lower than the usual temperature of a solidification anneal, but sufficient to guarantee the adherence of the resist to the underlying substrate. The object of such a drying is to obtain a pre-hardening of the resist, that is, to bring the resist to a state where, although non-liquid, it adheres to the substrate while keeping some “flexibility”. Such a state is conventionally prohibited. The drying temperature and duration conditions are chosen so that, despite this flexibility, the resist ensures its protective function. Its state must thus be such that the resist, during wafer handlings, is not scratched, and catches no polluting elements.

For a resist of SC RESIST type, either a relatively long drying at ambient temperature, or a relatively short drying at higher temperature, but smaller than that of a conventional solidification anneal, is performed. For example, for a resist SC100, the drying will have a temperature on the order of twenty-one degrees Celsius plus or minus one degree (21° C.±1° C.) for approximately thirty minutes. To obtain the same state, resist SC100 may also be dried on a heating plate at at most sixty-five degrees Celsius for at most ten seconds.

25. Selective exposure, according to known techniques, of the sole rear surface of the semiconductive wafer, according to the etch pattern desired for at least the resist layer.

26. Hardening and “developing”. This step includes a second anneal performed in conventional conditions at a high temperature, determined by the nature of the photosensitive material. For example, for a resist of SC100 type, the anneal is performed at a temperature ranging between 80 and 100° C., for example, approximately 85° C. (±5° C.) for substantially thirty minutes.

After exposure and hardening steps 25 and 26, the resist surface exhibits, as illustrated in FIG. 3 detailed hereafter, deformations (D, FIG. 3) at the limits between the regions respectively exposed (3-1) and unexposed (3-2) to radiation. Indeed, upon exposure, only the exposed resist regions are polymerized. Then, since the structure of these exposed regions differs from that of the unexposed neighboring regions, a mechanical stress appears at the borders between two different regions. At the subsequent hardening anneal, the stress appears as deformations that are then fixed. The deformations then “develop”, at the resist surface, the exposure mask pattern. This “development” can then be used to align a mask on the other wafer surface.

The studies carried out by the present inventor have shown that the deformations characterize by a depression having a given slope. This slope is reproducible and essentially depends on the nature and on the thickness of the photosensitive material used, on its flexibility before exposure, that is, on the conditions (temperature and duration) of the pre-hardening drying (step 24), as well as on the conditions of the hardening anneal (step 26) at higher temperature.

At this point, the front surface is not exposed. Accordingly, the resist covering is not polymerized.

27. Exposure of the front surface. The wafer is turned over and realigned. The realignment is possible since the pattern “revealed” on the rear surface can be detected by optical devices conventionally used by equipment such as machine MA150. The front surface can then be selectively exposed according to the desired etch pattern, the position of the etch mask being perfectly determined with respect to the desired rear surface etch pattern. For the rear surface resist to keep intact the information of the etch mask specific to it, the sole front surface is selectively exposed.

28. Simultaneous development, in a single step, of both wafer surfaces.

29. Anneal, intended for evaporating the etch solvents of the non-polymerized regions of the resist and for hardening the polymerized resist areas on both surfaces before the subsequent processing.

30. Processing, for example etching, of the two substrate surfaces. Such an etching may be performed by any known method of dry or wet etching type.

31. Removal. Single final wafer cleaning step (removal of the polymerized resist areas on both surfaces and removal of the impurities).

FIG. 3 illustrates a partial simplified cross-section view of the state of the rear surface of a wafer at the end of step 25 of the method according to the present invention.

The wafer is formed of a semiconductor substrate 1, for example made of silicon. It is assumed, as previously discussed, that the front surface (not shown) and the rear surface (shown) of substrate 1 are formed of a layer 2 of a same material. Layer 2 is covered with a photosensitive material layer, for example a resist of negative type 3. After exposure step 25, the resist includes exposed regions 3-1 and unexposed regions 3-2. At the limits between regions 3-1 and 3-2, mechanical stress is created in resist 3. This stress appears in the subsequent hardening anneal as deformations D of the surface of present resist 3 as previously discussed in relation with steps 25 and the following of FIG. 2. Deformations D draw or “develop”, at the rear surface, the exposure mask pattern.

The method according to the present invention enables avoiding the complete processing (development and etching) of a first (rear) surface of a wafer before processing the second one (front surface). This enables significant reduction of a double-faced processing sequence. Further, the phenomenon of development, according to the present invention, of a resist etch pattern on the first surface, is particularly simple to implement, as appears from the foregoing description. In practice, this enables advantageously passing from a double-faced process with at least eighteen different steps (1-9, 11-19, FIG. 1) to a process with eleven steps only (21-31, FIG. 2).

The previously-discussed principles applied to a double-faced etching of the substrate —that is, of the very substrate and/or of one or several layers formed on its surfaces—also apply to any other processing. Step 31 of processing of the two surfaces may, for example, be a double-faced implantation. Such an implantation may be intended either for doping specific surface wells/regions from each surface, or for forming through the entire substrate thickness a through well. In such doping cases, a layer, generally an insulating layer of small thickness, is interposed between the resist and the substrate. Those skilled in the art will know how to determine, according to the manufacturing process, if and/or when this layer is to be removed or maintained. The present invention also enables in such doping applications avoiding the use of a complete rear surface processing.

Of course, the present invention is likely to have various alterations, modifications, and improvements which will readily occur to those skilled in the art. In particular, those skilled in the art will know how to adapt the temperatures of the different heating operations (drying or anneal) to the photosensitive material used and to the searched result (pre-hardening, solidification or hardening of a specific photosensitive material). Further, it has been assumed in the foregoing description that the photosensitive material is a resist of family SC RESIST sold by Arch Chemicals Company. However, it may be any other negative resist of similar characteristics (composition, viscosity...) but sold under a different name by this same company or another.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for processing front and rear surfaces of a semiconductor substrate, including the steps of:
depositing on the front surface a photosensitive material of negative type;
annealing the substrate at a relatively high temperature;
turning over the substrate;
depositing the photosensitive material on the rear surface;
drying said material so that it adheres to the substrate while keeping some flexibility;
exposing, according to a desired pattern, regions of the photosensitive material on the rear surface;
annealing to solidify the photosensitive material;
turning over the substrate and realigning it using rear surface deformations defining the first pattern in the photosensitive material, obtained by the preceding steps of drying, rear surface exposing and annealing;
exposing the front surface, according to a second etch pattern;
simultaneously developing the two surfaces; and
simultaneously processing on both surfaces the substrate portions exposed by the openings in the photosensitive material performed at the preceding step of simultaneously developing the two surfaces.

2. The method of claim 1, wherein the drying step is performed at a temperature close to the ambient temperature.

3. The method of claim 2, wherein the drying step is performed at substantially 21° C. for thirty minutes.

4. The method of claim 1, wherein the drying step comprises a ten-second stay on a plate heated to approximately 65° C.

5. The method of claim 1, wherein the annealing step to solidify the photosensitive material is performed at a temperature ranging between 80° C. and 100° C.

6. The method of claim 1, wherein the step of simultaneous development of the two surfaces includes the steps of:
removing from the two surfaces the selectively unexposed regions of the photosensitive material; and
annealing, at a relatively high temperature, to evaporate etch and hardening solvents of the regions of the photosensitive material that have been left in place.

7. The method of claim 1, wherein the step of simultaneous processing of the substrate on the two surfaces includes a double-faced doping.

8. The method of claim 1, wherein the step of simultaneous processing of the substrate on the two surfaces includes a double-faced etching of the same material.
